(19) United States
(12) Patent Application Publication
(10) Pub. No.: US 2025/0149881 A1
(43) Pub. Date: May 8, 2025

(54) SEMICONDUCTOR DEVICE

(71) Applicant: Renesas Electronics Corporation, Tokyo (JP)

(72) Inventors: Koki NARITA, Tokyo (JP); Naoaki HIYAMA, Tokyo (JP)

(21) Appl. No.: 18/918,189

(22) Filed: Oct. 17, 2024

(30) Foreign Application Priority Data
Nov. 7, 2023 (JP) 2023-189973

(51) Int. Cl. H02H 9/04; H01L 27/02

(52) U.S. Cl. CPC H02H 9/046; H10D 89/611; H10D 89/811

(57) ABSTRACT

A semiconductor device having a semiconductor chip with a first circuit, a second circuit, a third circuit, a first protection element, and a resistor circuit, the first circuit and the third circuit mutually input and output unidirectional or bidirectional signals via the second circuit, the first protection element is electrically connected to a first node which electrically connects a first terminal and the second circuit, and the resistor circuit is provided between the first node and a second node which electrically connects the first terminal, the first circuit, and the second circuit and is located upstream of the first node.

### CROSS-REFERENCE TO RELATED APPLICATIONS

The disclosure of Japanese Patent Application No. 2023-189973 filed on Nov. 7, 2023 including the specification, drawings and abstract is incorporated herein by reference in its entirety.

### BACKGROUND

This disclosure relates to a semiconductor device, and particularly relates to a semiconductor device including a protection element.

The charged device model (CDM) test is a withstand voltage evaluation method using a model of electrostatic discharge in a semiconductor chip. In this test, the CDM withstand voltage is evaluated by generating discharge by contacting a ground terminal (ground conductor) with a test pin with an entire semiconductor chip being in a charged state.

In the semiconductor process, the gate oxide film of the MOS (Metal Oxide Semiconductor) transistor is becoming thinner due to miniaturization, resulting in the significant decrease in the gate withstand voltage. For this reason, the gate breakdown of the MOS transistor is likely to occur during the electrostatic breakdown test (in particular, CDM test) for evaluating the ESD (electrostatic discharge) resistance. This tendency is particularly noticeable in a MOS transistor that transmits and receives signals across different power supplies in a semiconductor chip in which analog circuits and digital circuits are mixed and different power supplies are provided for each of them.

There are disclosed techniques listed below.

### [Patent Document 1] Japanese Unexamined Patent Application Publication No. 2017-037949

Patent Document 1 discloses a semiconductor device in which a protection element is connected to an internal node between a bias circuit and a clock oscillator and a protection resistor is inserted between the internal node and a power supply of an analog circuit.

In this way, an ESD discharge path is formed to allow a part of ESD current flow through the protection resistor and a voltage drop is caused between the power supply of the analog circuit and the internal node, so that the ESD stress voltage applied to the signal line across different power supplies can be divided and reduced.

### SUMMARY

In highly integrated semiconductor chips such as 3 nm process products, inserting a protection resistor with a large resistance value may cause a phase locked loop (PLL) to be unable to operate due to demand for faster clock frequencies and influences of decrease in power supply voltage of an analog circuit.

In order to solve this problem, it is necessary to increase the current supplied to an oscillator. However, when the resistance value of the protection resistor is large, the voltage drop between the power supply of the analog circuit and the internal node increases during the normal operation, so that the voltage of the internal node decreases, making the oscillator unable to operate.

With the decrease in the withstand voltage of the transistor due to process miniaturization, there is a need to lower the power supply voltage of the analog circuit. Therefore, the margin for the amount of voltage drop between the power supply of the analog circuit and the internal node becomes smaller as compared with prior arts, making it more difficult to use a protection resistor with a large resistance value in terms of circuit design.

Other problems and novel features will become apparent from the description of this specification and the accompanying drawings.

A semiconductor device according to this disclosure includes a semiconductor chip including a first circuit region, a second circuit region with a ground voltage different from a ground voltage of the first circuit region, a first protection element, and a resistor circuit, the first circuit region includes a first terminal to which a power supply voltage is supplied, a first circuit electrically connected to the first terminal, and a second circuit electrically connected to the first terminal and the first circuit and having a smaller power consumption than the first circuit, the second circuit region includes a third circuit electrically connected to the second circuit, the first circuit and the third circuit mutually input and output unidirectional or bidirectional signals via the second circuit, the first protection element is electrically connected to a first node which electrically connects the first terminal and the second circuit, and the resistor circuit is provided between the first node and a second node which electrically connects the first terminal, the first circuit, and the second circuit and is located upstream of the first node.

According to this disclosure, it is possible to provide a semiconductor device capable of ensuring a circuit operation voltage while strengthening the ESD resistance of a circuit unit configured to transmit and receive signals across different power supplies.

### BRIEF DESCRIPTION OF THE DRAWINGS

FIG. 1 is a configuration diagram of a semiconductor chip provided in a semiconductor device according to this disclosure.

FIG. 2 is a configuration diagram of the semiconductor chip provided in the semiconductor device according to this disclosure.

FIG. 3 is a configuration diagram of the semiconductor chip provided in the semiconductor device according to this disclosure.

FIG. 4 is a configuration diagram of the semiconductor chip provided in the semiconductor device according to this disclosure.

FIG. 5 is a configuration diagram of the semiconductor chip provided in the semiconductor device according to this disclosure.

### DETAILED DESCRIPTION

Hereinafter, embodiments of this disclosure will be described in detail with reference to drawings. In the specification and drawings, the same or corresponding components are denoted by the same reference numerals and redundant descriptions are omitted. In the drawings, some configurations are sometimes omitted or simplified for convenience of description. Each of the embodiments may be combined with each other as appropriate at least partially.

In the semiconductor device according to this disclosure, the configuration in which the conductivity type (p type or n type) of a semiconductor substrate, a semiconductor layer, a diffusion layer (diffusion region), and others is reversed is also possible. For this reason, when one conductivity type of the n type and the p type is defined as a first conductivity type and the other conductivity type is defined as a second conductivity type, it is possible to set the first conductivity type as the p type and the second conductivity type as the n type, and it is also possible to reversely set the first conductivity type as the n type and the second conductivity type as the p type.

Also, the expression “connect” in this disclosure includes the meaning of “electrically connect” unless “directly connect” is described in particular.

### First Embodiment

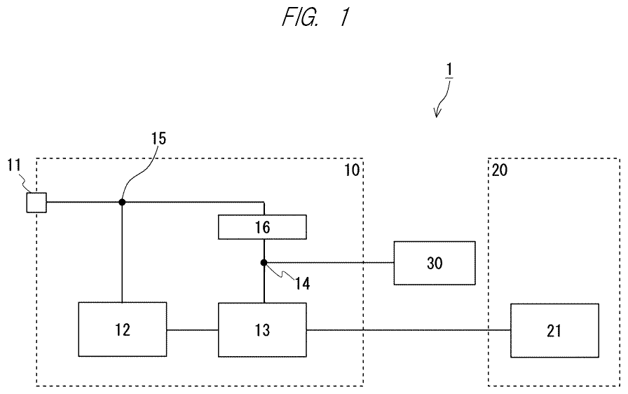

Hereinafter, a configuration example of a semiconductor chip 1 provided in a semiconductor device according to this disclosure will be described with reference to FIG. 1. The semiconductor chip 1 illustrated in FIG. 1 includes at least a first circuit region 10, a second circuit region 20, and a first protection element 30. Also, the second circuit region 20 is driven by a ground voltage different from that of the first circuit region 10.

The first circuit region 10 includes at least a first terminal 11, a first circuit 12, and a second circuit 13. The first terminal 11 is a terminal to which a power supply voltage is supplied from outside. The first terminal 11 is electrically connected to the first circuit 12 and the second circuit 13 whose power consumption is smaller than that of the first circuit 12.

The second circuit region 20 includes at least a third circuit 21. The third circuit 21 is electrically connected to the second circuit 13, and the first circuit 12 and the third circuit 21 are thus electrically connected to each other via the second circuit 13. Further, the first circuit 12 and the third circuit 21 mutually input and output unidirectional or bidirectional signals via the second circuit 13.

The first protection element 30 is electrically connected to a first node 14 which electrically connects the first terminal 11 and the second circuit 13. The first protection element 30 will be described in detail later.

A resistor circuit 16 is provided between the first node 14 and a second node 15 which electrically connects the first terminal 11, the first circuit 12, and the second circuit 13 and is located upstream of the first node 14. The resistor circuit 16 will also be described in detail later.

With the above configuration, it is possible to provide a semiconductor device capable of ensuring a circuit operation voltage while strengthening the ESD resistance of a circuit unit configured to transmit and receive signals across different power supplies.

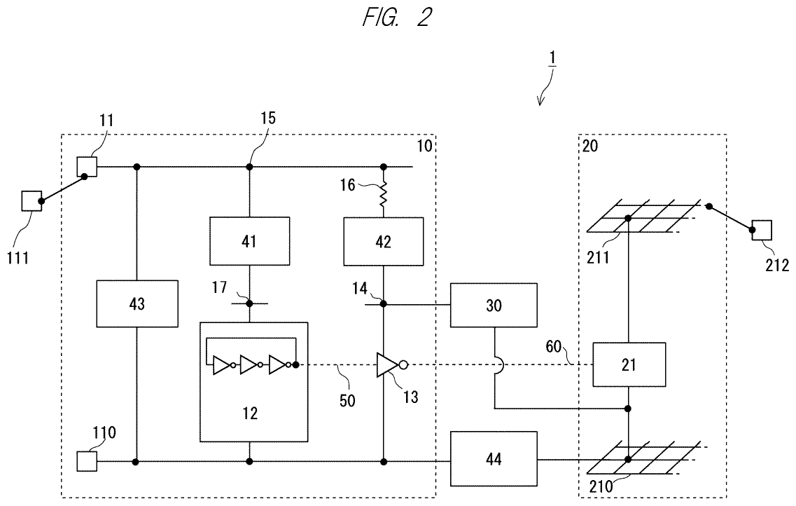

Next, a configuration example of the semiconductor chip 1 will be described in detail with reference to FIG. 2.

In the semiconductor chip 1, the second circuit region 20 has a larger area than the first circuit region 10. Also, the semiconductor device according to this disclosure operates favorably when the areas of the wirings, wells, and diffusion layers to which the power supply voltage and ground voltage are supplied in the second circuit region 20 are larger than those in the first circuit region 10.

For example, the first circuit region 10 is an analog circuit region, and the second circuit region 20 is a digital circuit region. In another aspect of this disclosure, the first circuit region 10 is a circuit region to which a power supply voltage and ground voltage used exclusively for IP (Intellectual Property) are supplied, and the second circuit region 20 is a circuit region to which a power supply voltage and ground voltage used in common by the semiconductor chip are supplied.

The IP refers to a circuit function block with a specific role, and the circuit region to which a power supply voltage and ground voltage used exclusively for IP are supplied (hereinafter referred to as “IP exclusive region”) refers to a circuit region in which analog-based IP that mainly processes analog signals is disposed.

Examples of analog-based IP include a PLL (Phase Locked Loop), a TRNG (True Random Number Generator), an oscillator, a temperature sensor, an analog-to-digital converter, and a digital-to-analog converter. Since these circuits are susceptible to noise, it is necessary to provide dedicated power supply voltage and ground voltage in order to prevent noise propagation from the circuit region to which a power supply voltage and ground voltage used in common by the semiconductor chip are supplied.

The circuit region to which a power supply voltage and ground voltage used in common by the semiconductor chip are supplied (hereinafter referred to as “chip common circuit region”) refers to a circuit region in which digital-based IP that mainly processes digital signals is disposed.

Examples of digital-based IP include a CPU (Central Processing Unit), an SRAM (Static Random Access Memory), and a flash memory. Since these circuits are less susceptible to noise as compared with analog-based IP, it is possible to use chip common power supply voltage and ground voltage used by multiple IPs. The first terminal 11 in the first circuit region 10 is electrically connected to a first external terminal 111 to which a power supply voltage is supplied from outside, and functions also as a test pin in the CDM test. Similarly, a second terminal 211 in the second circuit region 20 is electrically connected to a second external terminal 212 different from the first external terminal 111.

The first circuit region 10 further includes a bias circuit 41, a bias circuit 42, and a protection circuit 43 in addition to the above-mentioned configuration. The bias circuit 41 is provided between the second node 15 and the first circuit 12, and the bias circuit 42 is provided between the resistor circuit 16 and the first node 14. Also, the protection circuit 43 is provided between the first terminal 11 which is connected to a power supply and a first ground 110.

The first circuit 12 and the third circuit 21 are electrically connected to each other via the second circuit 13, and thus mutually input and output unidirectional or bidirectional signals via the second circuit. In FIG. 2, a first signal 50 output from the first circuit 12 to the second circuit 13 is a signal that passes through the same power supply. The first signal 50 is processed in the second circuit 13 to be converted into a second signal 60 that passes across different power supplies, and is output to the third circuit 21.

Alternatively, the configuration in which the first signal 50 is output from the third circuit 21 to the second circuit 13, the first signal 50 is processed in the second circuit 13 to be converted into the second signal 60, and the second signal 60 is output to the first circuit 12 is also possible. This configuration will be described in the third embodiment.

In addition to the configuration of the first embodiment, the second circuit region 20 further includes the second terminal 211 to which a power supply voltage (ground voltage supplied to the second circuit region 20) different from that of the first circuit region 10 is supplied, and the third circuit 21 is provided between the second terminal 211 and a second ground 210.

In addition, a protection circuit 44 is provided between the first ground 110 and the second ground 210. In this way, a discharge path for the ESD current is formed between the first ground 110 and the second ground 210.

In the case where the second circuit region 20 has a larger area than the first circuit region 10, a large amount of charge accumulated in the second circuit region 20 flows into the first circuit region 10. This causes electrostatic breakdown because a large ESD stress voltage is applied between the first circuit region 10 and the second circuit region 20.

In addition, in the negative CDM test in which a negative charge is charged in the semiconductor to be tested and the charged charge is discharged from the test terminal, when the first terminal 11 is used as the test terminal, the CDM current entering from the first terminal 11 flows through the protection circuits 43 and 44 to the second circuit region 20. Therefore, a large ESD stress voltage corresponding to that of two stages of protection circuits is applied to the third circuit 21 that receives the second signal 60 (the signal that passes across different power supplies), which causes electrostatic breakdown.

If the ESD stress voltage applied to the third circuit 21 cannot be suppressed below the breakdown withstand voltage by only the protection circuits 43 and 44, a method of dividing and reducing the ESD stress voltage of the first node 14 and the second signal 60 by providing a discharge path via the resistor circuit 16 and the first protection element 30 can be adopted. However, if the first circuit 12 is a circuit that consumes a large amount of current during normal operation such as an oscillator that generates a clock signal with a frequency of about several GHz, inserting the high-resistance resistor circuit 16 increases the voltage drop applied to both ends of the first circuit 12 due to the circuit operation current that flows during normal operation. This may cause the first circuit 12 to be unable to operate satisfactorily.

Furthermore, with the decrease of the withstand voltage of transistor due to process miniaturization, it is necessary to lower the power supply voltage, and thus the margin for the amount of voltage drop between the first terminal 11 and the node (third node 17) between the first circuit 12 and the bias circuit 41 becomes smaller, so that it is required in terms of circuit design to lower the resistance value of the resistor circuit 16 and the first protection element 30.

The semiconductor device according to this disclosure has the configuration in which the second circuit 13 which is a buffer circuit whose power consumption is smaller than that of the first circuit 12 and the bias circuit 42 for the buffer circuit are provided in the first circuit region 10, and the signal from the first circuit 12 is transmitted to the second circuit region 20 via the second circuit 13.

Furthermore, it is preferable that the first protection element 30 is provided between the first node 14 and the second ground 210 of the second circuit region 20, and the resistor circuit 16 is provided between the first node 14 and the second node 15 that electrically connects the first terminal 11, the first circuit 12, and the second circuit 13 and is located upstream of the first node 14. In this disclosure, the expression “located upstream” means that, when the first terminal 11 is taken as the starting point, the second node 15 is located at an electrically closer position to the first terminal 11 than the first node 14 is. In addition, it is preferable that the first node 14 is not connected to the third node 17 and is electrically isolated therefrom.

With the above configuration, the amount of voltage drop occurring in the resistor circuit 16 during normal operation can be reduced, so that it is no longer indispensable to reduce the resistance value of the resistor circuit 16. Therefore, it is possible to provide a semiconductor device capable of ensuring a circuit operation voltage while strengthening the ESD resistance for the signal portion passing across different power supplies.

Next, each component of the semiconductor device according to this disclosure will be described. A specific example of the first circuit 12 is a ring oscillator composed of a multi-stage inverter circuit, and a specific example of the second circuit is an inverter circuit. Having a smaller number of elements constituting the circuit and being smaller also in element size in comparison with a ring oscillator, an inverter circuit consumes less power and is suitable for the semiconductor device according to this disclosure.

The bias circuits 41 and 42 are circuits that generate a reference power supply and reference current that allow the circuits (first circuit 12 and second circuit 13) located downstream of the bias circuits to operate properly.

The protection circuit 43 is provided between the first terminal 11 and the first ground 110, and a GCNMOS (Gate Controlled N-type Metal Oxide Semiconductor) with a channel width of 1000 to 10000 μm is used as an example. The protection circuit 44 is provided between the first ground 110 and the second ground 210, and a bidirectional diode with an anode-cathode facing length of 100 to 1000 μm is used as an example. Each protection circuit forms a discharge path for the ESD current and has the role of releasing the ESD current to an external terminal. The impedance value of the discharge path formed of these protection circuits is about several tenths of an ohm to several ohms.

The first protection element 30 is preferably formed of a PMOS transistor or an NMOS transistor with a channel width of several μm to several tens of μm. Also, the first protection element 30 may also be formed of a plurality of diodes with a facing length of 1 to 100 μm.

The resistor circuit 16 is preferably formed of a resistor with a resistance of several tens to several thousands of ohms. The resistor circuit 16 may be provided between the bias circuit 42 and the first node 14 other than the position illustrated in FIG. 2. The impedance value of the resistor circuit 16 is about several tens to several thousands of ohms, and the resistor circuit 16 may be formed of transistors that can obtain a similar impedance value.

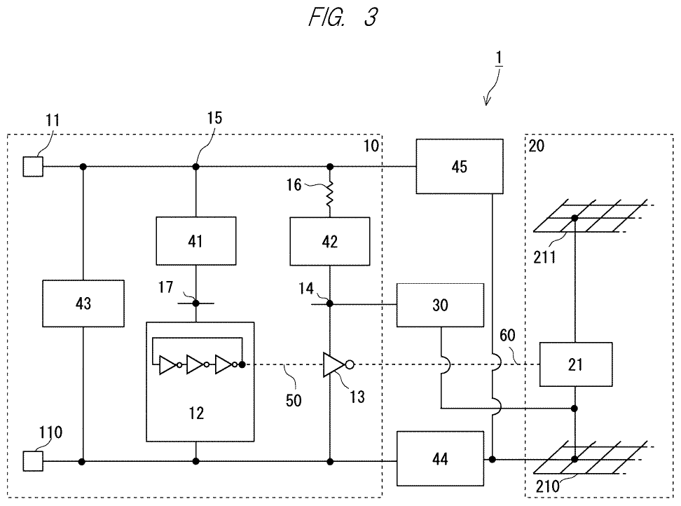

Also, as illustrated in FIG. 3, a protection circuit 45 serving as a second protection element may be connected so as to electrically short-circuit between the first terminal 11 of the first circuit region 10 and the second ground 210 of the second circuit region 20. By providing the protection circuit 45, the CDM current flowing from the first terminal 11 can be dispersed into two discharge paths including one through the protection circuits 43 and 44 and the other through the protection circuit 45. Therefore, it is possible to reduce the ESD stress voltage as compared with the case of only the one discharge path through the protection circuits 43 and 44.

Since the protection circuit 45 may have the same configuration as the protection circuit 43, the impedance of the discharge path formed of the protection circuit 45 is about several tenths of an ohm to several ohms. Therefore, the impedance value of the resistor circuit 16 is larger than that of the protection circuit 45 serving as the second protection element.

With the above configuration, it is possible to provide a semiconductor device capable of ensuring a circuit operation voltage while strengthening the ESD resistance of a circuit unit configured to transmit signals across different power supplies.

### Second Embodiment

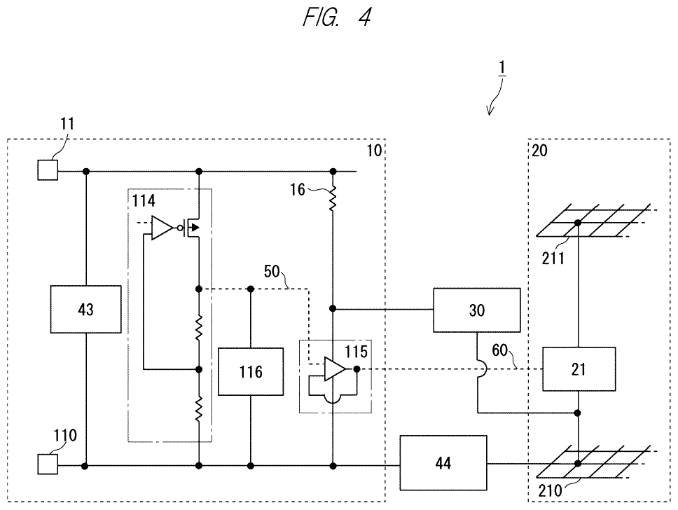

In this embodiment, a modification of the semiconductor chip 1 provided in the semiconductor device according to the first embodiment will be described in detail with reference to FIG. 4. Note that the same configuration as that of the first embodiment may be omitted in order to avoid repetitive description.

A fourth circuit 114 provided in the first circuit region 10 according to this embodiment is a regulator circuit for an analog circuit, a fifth circuit 115 is a unity gain buffer circuit, and a sixth circuit 116 is an analog circuit.

The fourth circuit 114 which is a regulator circuit generates internal voltages such as a secondary power supply and a reference voltage to be applied to the sixth circuit 116 which is an analog circuit. The fifth circuit 115 which is a unity gain buffer circuit outputs the internal voltage input to the analog circuit to the second circuit region 20 which is a digital circuit region. Here, it is preferable that the fifth circuit 115 which is a unity gain buffer circuit is configured to have a smaller number of components or smaller element size so as to consume less current than the fourth circuit 114 which is a regulator circuit.

In the configuration in which an internal voltage generated in an analog circuit region is output to a digital circuit region, providing the resistor circuit 16 in the regulator circuit is not preferable because a large voltage drop occurs in the resistor circuit 16 when the regulator consumes a large current, resulting in the drop in voltage level of the first signal.

On the other hand, with the configuration according to this disclosure provided with the unity gain buffer circuit and the resistor circuit 16 located upstream of the unity gain buffer circuit, it is possible to provide a semiconductor device capable of ensuring a circuit operation voltage while strengthening the ESD resistance of a circuit unit configured to transmit signals across different power supplies.

### Third Embodiment

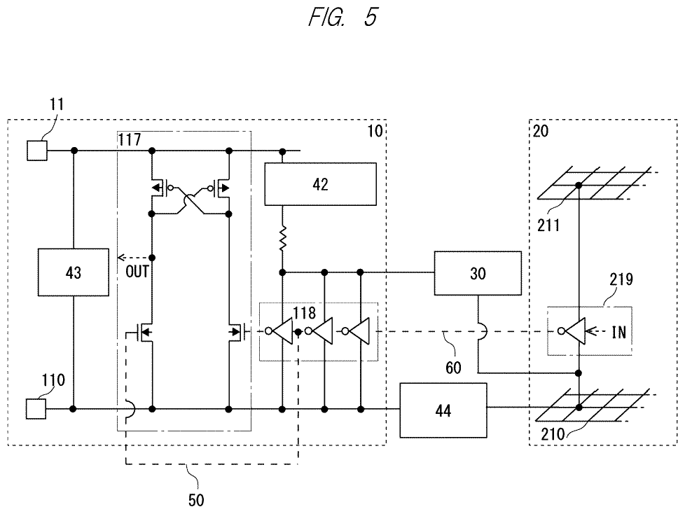

In this embodiment, a modification of the semiconductor chip 1 provided in the semiconductor device according to the first and second embodiments will be described in detail with reference to FIG. 5. Note that the same configuration as those of the first and second embodiments may be omitted in order to avoid repetitive description.

A seventh circuit 117 provided in the first circuit region 10 according to this embodiment is a signal output circuit of a level shifter, an eighth circuit 118 is a buffer circuit, and a ninth circuit 219 provided in the second circuit region 20 is a signal input circuit of the level shifter. Therefore, the semiconductor chip 1 according to this embodiment has a configuration in which a signal is passed from the second circuit region 20 which is a digital circuit region to the first circuit region 10 which is an analog circuit region.

The ninth circuit 219 which is a signal input circuit of the level shifter is preferably composed of an inverter circuit.

The eighth circuit 118 which is a buffer circuit is preferably composed of a multi-stage inverter circuit, and it is preferable that the eighth circuit 118 is configured to have a smaller number of components or smaller element size so as to consume less current than the seventh circuit 117 which is a signal output circuit of the level shifter. With the above configuration, it is possible to provide a semiconductor device capable of ensuring a circuit operation voltage while strengthening the ESD resistance of a circuit unit configured to transmit signals across different power supplies.

Although the invention made by the inventors of this application has been specifically described based on embodiments, it goes without saying that the present invention is not limited to the above embodiments and may be modified in various ways within the range not departing from the gist of the present invention.

What is claimed is:

1. A semiconductor device comprising a semiconductor chip including a first circuit region, a second circuit region with a ground voltage different from a ground voltage of the first circuit region, a first protection element, and a resistor circuit,
wherein the first circuit region includes:
a first terminal to which a power supply voltage is supplied;
a first circuit electrically connected to the first terminal; and
a second circuit electrically connected to the first terminal and the first circuit and having a smaller power consumption than the first circuit,
wherein the second circuit region includes a third circuit electrically connected to the second circuit,
wherein the first circuit and the third circuit mutually input and output unidirectional or bidirectional signals via the second circuit,
wherein the first protection element is electrically connected to a first node which electrically connects the first terminal and the second circuit, and
wherein the resistor circuit is provided between the first node and a second node which electrically connects the first terminal, the first circuit, and the second circuit and is located upstream of the first node.

2. The semiconductor device according to claim 1, further comprising:
a second terminal supplied with the ground voltage of the second circuit region and electrically connected to the third circuit; and
a second protection element connected to electrically short-circuit the first terminal and the second terminal,
wherein an impedance value of the resistor circuit is larger than that of the second protection element.

3. The semiconductor device according to claim 2,
wherein the first circuit region is an analog circuit region, and
wherein the second circuit region is a digital circuit region.

4. The semiconductor device according to claim 3,
wherein a first signal is output from the first circuit to the second circuit, and
wherein the first signal is processed into a second signal in the second circuit and is then output to the third circuit.

5. The semiconductor device according to claim 4,
wherein the first circuit is a ring oscillator composed of a multi-stage inverter circuit, and
wherein the second circuit is an inverter circuit.

6. The semiconductor device according to claim 2,
wherein the first circuit region is a circuit region to which a power supply voltage and ground voltage used exclusively for IP (Intellectual Property) are supplied, and
wherein the second circuit region is a circuit region to which a power supply voltage and ground voltage used in common by the semiconductor chip are supplied.

7. The semiconductor device according to claim 2,
wherein areas of wirings, wells, and diffusion layers to which a power supply voltage and ground voltage are supplied in the second circuit region are larger than those in the first circuit region.

8. The semiconductor device according to claim 3,
wherein a first signal is output from the third circuit to the second circuit, and
wherein the first signal is processed into a second signal in the second circuit and is then output to the first circuit.

9. The semiconductor device according to claim 4,
wherein the first circuit is a regulator circuit configured to output an arbitrary voltage, and
wherein the second circuit is a unity gain buffer circuit.

10. The semiconductor device according to claim 8,
wherein the first circuit, the second circuit, and the third circuit constitute a level shifter,
wherein the first circuit is a signal output circuit of the level shifter,
wherein the second circuit is a multi-stage inverter circuit, and
wherein the third circuit is a signal input circuit of the level shifter.

11. The semiconductor device according to claim 1,
wherein the resistor circuit is formed of a resistor.

12. The semiconductor device according to claim 1,
wherein the resistor circuit is formed of a transistor.

13. The semiconductor device according to claim 1,
wherein the first protection element is formed of a PMOS transistor or an NMOS transistor.

14. The semiconductor device according to claim 1,
wherein the first protection element is formed of a plurality of diodes.

15. The semiconductor device according to claim 2,
wherein the first terminal is electrically connected to a first external terminal, and
wherein the second terminal is electrically connected to a second external terminal different from the first external terminal.
